(19) United States
(12) Patent Application Publication
(10) Pub. No.: US 2010/0220444 A1
(43) Pub. Date: Sep. 2, 2010

(54) CONTROL UNIT

(76) Inventors: Klaus Voigtlaender, Wangen (DE); Peter Kimmich, Schoenaich (DE)

Correspondence Address: MICHAEL J. STRIKER, 103 EAST NECK ROAD, HUNTINGTON, NY, 11743, US

(21) Appl. No.: 12/682,933

(22) PCT Filed: Feb. 25, 2009
(86) PCT No.: PCT/EP2009/052182

§ 371 Date: Apr. 14, 2010

(30) Foreign Application Priority Data
Mar. 12, 2008 (DE) 10 2008 000 621.1

(51) Int. Cl. H05K 7/20

(52) U.S. Cl. 361/689; 361/688

(57) ABSTRACT

The invention relates to a control unit (4) having at least one base (1) and a circuit carrier (2) associated therewith and a cover (3), which closes the control unit, wherein said control unit can be brought to a desired temperature with the aid of a substrate which dissipates heat and/or components which dissipate heat. The substrate is received by cooling paths at least inside the control unit.

### BACKGROUND INFORMATION

Many control units in motor vehicles are composed of at least 3 components, i.e., a base, a circuit carrier, and a cover. It is important to ensure that good thermal contact exists between the circuit carrier and the power electronics, and between the two housing parts. The temperature of the circuit carrier and the power electronics rises during operation. Heat is typically dissipated, e.g., with the aid of cooling ribs that are provided on the two housing parts. They are used to dissipate the dissipation heat that is produced.

A disadvantage of this method is that the tolerances must be narrow in order to ensure that heat is reliably dissipated. However, maintaining very narrow tolerances increases the cost to manufacture circuit carriers of this type. Heat may also be dissipated with the aid of water cooling, the Peltier effect, heat exchangers, or fans. Implementing devices of this type is a very difficult and complex undertaking, however, particularly in motor-vehicle construction.

It is known to direct heat through the circuit carrier and into the heat sink. Heat may be dissipated directly to the heat sink with the aid of pastes, adhesives, or solids that are inserted between the components. The capillary effect of thin tubes, in which water is drawn upward against the force of gravity, is also known, and so this effect may also be used to dissipate heat.

In control units, in particular for larger performance classes, considerable quantities of heat are produced, which must be dissipated via cooling paths. For this purpose, cooling ribs are often installed on the housing, and thermally conductive pastes or solids are also applied. This is very costly.

### DISCLOSURE OF THE INVENTION

According to the present invention, the control unit includes at least one base and a circuit carrier assigned thereto, and a cover that closes the control unit; the control unit may be brought to a desired temperature with the aid of a heat-dissipating substrate and/or heat-dissipating components. As a result, the substrate is accommodated by cooling paths, at least inside the control unit. Due to the design of the control device according to the present invention, it is possible, in particular, to eliminate the use of pastes and solids.

It is advantageous that the cooling paths are designed as recesses and/or ducts. An improved cooling effect is attained via the use of short paths with the aid of these cooling paths which are integrated in the control unit. The cooling paths may be easily formed in existing housings, including very small housings. The resultant temperature stress is minimal. In addition, control units that are designed in this manner may be exposed to large temperature fluctuations. Since very little installation space is required, weight may be reduced, and construction costs may therefore be reduced.

It is also advantageous that the cooling paths are designed as flat recesses. The cooling paths may be formed in existing housings. Housings of this type may withstand large temperature fluctuations without sustaining damage.

Furthermore, it is advantageous that the cooling paths are interconnected and that the cooling fluid may circulate within the cooling paths.

It is also advantageous that the wide cooling paths are approximately twice as wide as the narrow cooling paths.

Furthermore, it is advantageous that the depth of the wide ducts or cooling paths is approximately half to twice as great as the depth of the narrow ducts or cooling paths.

It is also advantageous that the cooling paths are provided in the base and/or in the circuit carrier and/or in the cover and have a depth that is less than 200 μm, or less than 120 μm, or between 10 μm and 120 μm, in particular between 50 μm and 110 μm.

In a further embodiment of the present invention, it is advantageous that the narrow cooling paths have a size between 5 μm and 200 μm, or between 10 μm and 150 μm, or between 80 μm and 120 μm.

It is likewise advantageous that the wide cooling paths have a size between 100 μm and 10 mm, or between 200 μm and 500 μm, or between 200 μm and 300 μm. The values stated for the narrow cooling paths, between 100 μm and 200 μm, represent ranges that may be selected depending on the embodiment.

Advantageously, the duct structure may be provided in the base of the control unit; the seal between the circuit carrier and the cover having the duct structure is very easy to handle. The seal is easy to realize for planar or structured based and covers.

In the context of the design and configuration according to the present invention, it is advantageous to form the cooling paths in groups and/or in various independent groups in the surface of the base, the circuit carrier, and the cover, in which case the individual groups are flow interconnected.

Furthermore, it is advantageous that, after the cooling fluid has entered the cooling paths of the control unit, a certain quantity of the cooling fluid is pumped back out in order to create an underpressure in the closed control unit.

In addition, it is advantageous that the cover and/or the base are composed of electrically conductive or electrically insulating material.

The invention will be described in greater detail below with reference to the drawing, which shows:

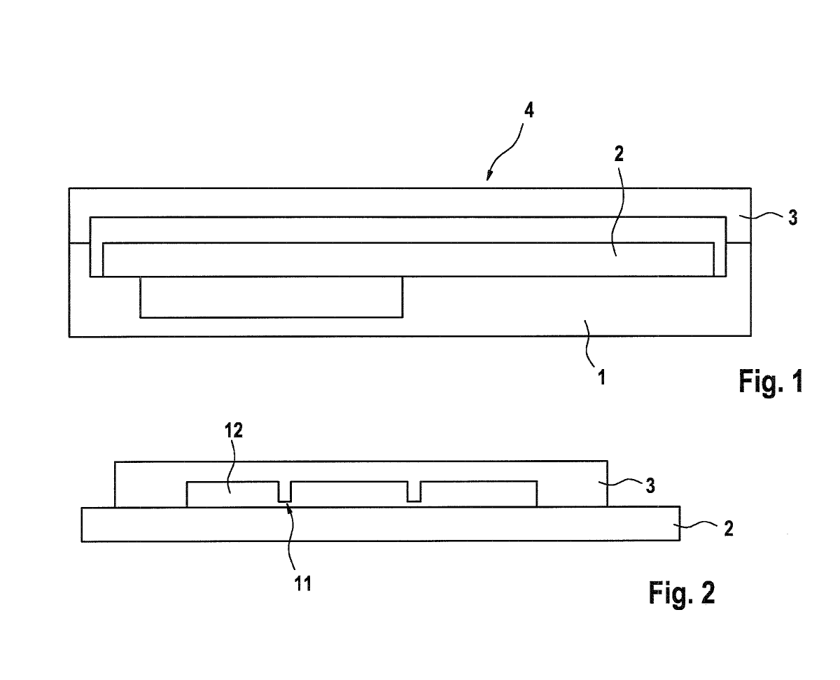

FIG. 1 shows a sectional view of a control unit that includes at least one base and a circuit carrier assigned thereto;

FIG. 2 shows a further embodiment of the control unit, in which flat ducts are formed in the cover;

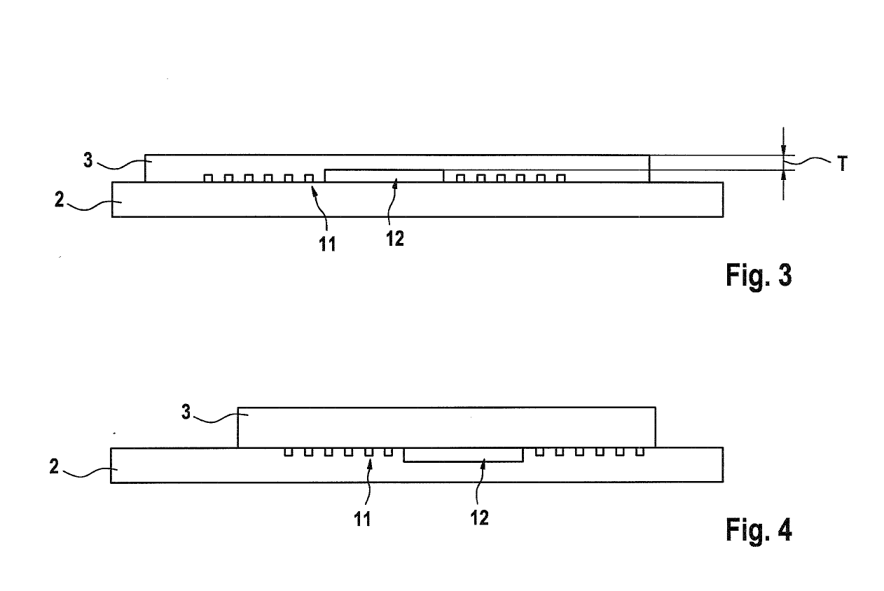

FIG. 3 shows a further embodiment of the control unit, in which deep and flat ducts are formed in the cover;

FIG. 4 shows a further embodiment of the control unit, in which deep and flat ducts are formed in the circuit carrier, which do not alternate but rather form groups;

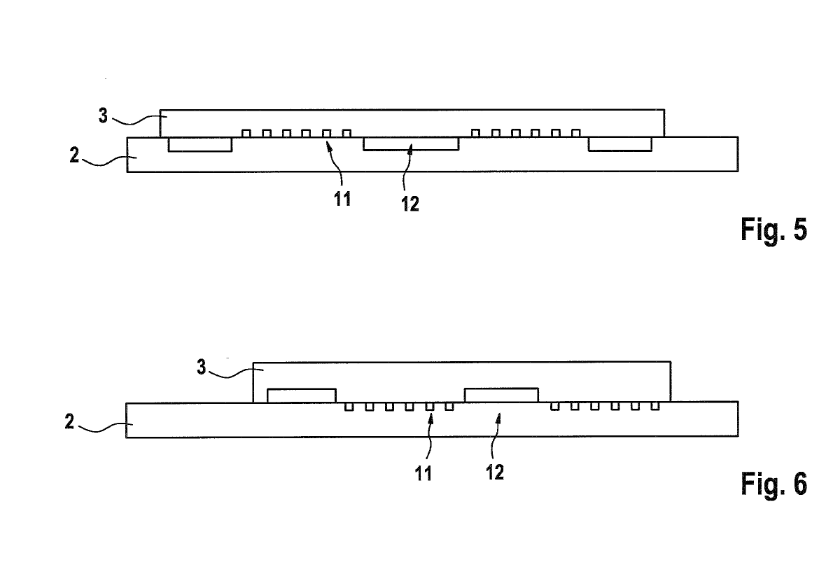

FIG. 5 shows a further embodiment of the control unit, in which deep ducts are formed in the circuit carrier, and flat ducts are formed in the cover;

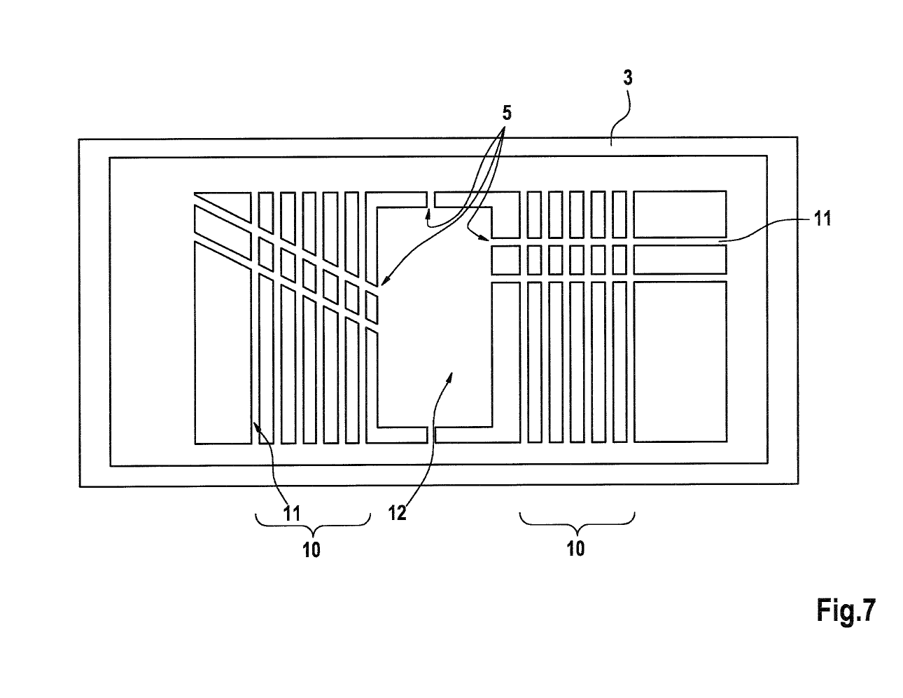

FIG. 6 shows a further embodiment of the control unit, in which flat ducts are formed in the circuit carrier, and deep ducts are formed in the cover, and this configuration may also be formed in the base;

FIG. 7 shows a top view according to FIG. 3, in which all ducts are interconnected;

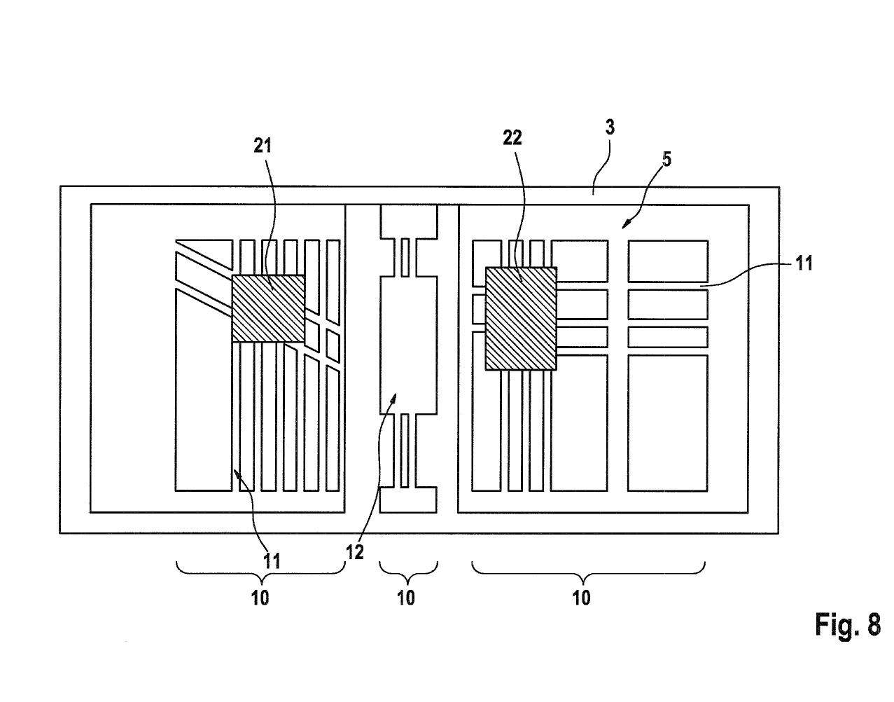

FIG. 8 shows a further embodiment of the control unit, in a top view, according to FIG. 3, including heat sources.

### EMBODIMENTS

As shown in the illustration in FIG. 1, a control unit 4 is equipped with at least one base 1 and a circuit carrier 2 assigned thereto, and a cover 3 that closes control unit 4. Control unit 4 may be brought to a desired temperature with the aid of a heat-dissipating substrate, which is not shown in the drawing, and/or heat-dissipating components. Cover 3 closes base 1 in a vacuum-tight manner.

To create an underpressure in closed control unit 4, after the cooling fluid has entered cooling paths 11 and/or 12 of control unit 4, a certain quantity of the cooling fluid is pumped back out. As a result, the contact pressure between cover 3 and base 1 is increased.

Recesses and/or ducts, which are also referred to below as cooling paths 11, 12, and which have a maximum depth T of 300 μm, are formed in one of the three parts, i.e., base 1, circuit carrier 2, and cover 3, on the inner sides of the particular component.

Cooling paths 11 may have a depth T that is less than 200 μm or less than 120 μm, or a depth between 10 μm and 120 μm, in particular between 50 μm and 110 μm.

These duct structures, in entirety, form one or more openings in the form of cavity systems and spaces. Once formed, these ducts are partially filled with water or another cooling fluid. This duct structure is sealed with the aid of a housing part or cover 3. Cover 3 closes control unit 4 in a vacuum-tight manner. Since it is possible to create high and low ducts, manufacturing the individual components is not as complex since the tolerances do not have to be as exact as they do in order to manufacture known control units.

As shown in FIG. 2, deep and flat ducts 11, 12 are formed in cover 3. This configuration may not be selected in the embodiment shown in FIG. 1 since it is ruled out via the installation of circuit carrier 2. Cooling paths 11 may also be provided only in base 1 or only in cover 3 or only in circuit carrier 2 or in all parts, i.e., in cover 3, circuit carrier 2, and base 1.

In FIG. 3, deep and flat ducts or cooling paths 11, 12 are formed in cover 3, and they are combined and interconnected with further cooling paths to form groups 10. It is also possible for groups 10 to not be interconnected. This design is possible because circuit carrier 3, as shown in FIG. 1, is eliminated. The same design as in cover 3 may also be provided in base 1.

In FIG. 4, deep and flat ducts, cooling paths, or cooling spaces 11, 12 are formed in circuit carrier 2; they do not alternate in sequence, but rather are combined into groups 10. Control unit 4 is closed by cover 3. Instead of the configuration of cooling paths 11, 12 in cover 3, it is also possible to form them in base 1, as mentioned above.

As shown in FIG. 5, deep, wide ducts and cooling paths 12 are formed in circuit carrier 2, while flat, narrow ducts and cooling paths 11 are provided in cover 3.

As shown in FIG. 6, deep, wide ducts and cooling paths 12 are formed in cover 3, and flat, narrow ducts and cooling paths 11 are provided in circuit carrier 2. This design may be provided in base 1 instead of cover 3.

FIG. 7 shows a top view of FIG. 3, and shows that all ducts and cooling paths 11, 12 are interconnected. Individual cooling paths 11 also include openings 5 that lead into the wide ducts or cooling paths 12. The ducts and cooling paths 11, 12 are designed as a cavity system.

FIG. 8 shows a further embodiment, in a top view similar to that shown in FIG. 3. In this embodiment, heat sources 21 and 22, which partially cover cooling channels 11, are provided. Depending on the performance that is required, these heat sources may be designed as bipolar transistors, IGBT, or MOSFETs. Furthermore, it is possible to use integrated circuits pC, ASIC or driver-Ics. It is possible, e.g., to form three cooling groups 10 that are interconnected.

After ducts, spaces, or cooling paths 11, 12 are formed or joined in the various components, a cooling fluid is added to the ducts until they are completely full. Finally, the cooling fluid is partially pumped back out of the ducts and cooling paths 11, 12 until a certain underpressure has been attained in control unit 4. Next, the openings may be closed, e.g., using laser welding devices for via forming, e.g., flanging, plugging, or bonding.

The fluid is retained in the smaller ducts via the capillary effect. Due to the underpressure that prevails in control unit 4, the larger ducts remain largely free of fluid.

When the electronic circuit is used on circuit carrier 2, the temperature may increase drastically due to the capillaries in the duct system, and so the fluid is heated locally beyond its boiling point and thereby escapes as steam. Due to the advantageous embodiment and configuration of cooling paths 11, it is possible to draw additional fluid out of the cooler regions of the ducts, and the fluid may condense at another point in the system due to the pressure and temperature conditions that exist within the various cavities. As a result, the external part of the control unit is held at a steady temperature, or it is cooled or warmed evenly.

It is also advantageous that additional cooling ribs are also provided on the outer side of control unit 4, next to capillaries of the finer duct system.

Narrow cooling paths 11 may have a size between 5 μm and 200 μm, or between 10 μm and 150 μm, or between 50 μm and 120 μm, or between 80 μm and 120 μm.

Wide cooling paths 12 have a size between 100 μm and 10 mm, or between 200 μm and 500 μm, or between 200 μm and 300 μm.

Circuit carrier 2 may include a printed circuit board composed of DCB (direct copper bonded), an IMS (isolated metal substrate), a stamped grid (lead frame), an LTCC (low temperature cofired ceramic), an HTCC (high temperature cofired ceramic), or a combination of these materials.

Base 1 and/or cover 3 may be composed of metallic, non-metallic, or composite materials that may be manufactured using a production method or a die casting method, or in drop forging via deep drawing or injection moulding or via extrusion moulding, extrusion, or blow molding.

The ducts or cooling paths 11, 12 are manufactured via moulding, etching, laser action, or milling. These cooling path sizes may be freely selected, with consideration for the capillary effect they will provide. It need only be ensured that the condensation process may take place outside of the smaller ducts.

When packed electronic components or assemblies are used, the lead frames or stamped grids may be provided with one or more duct structures. Furthermore, it is possible to provide the duct structure according to the present invention in the surface of blank chips.

The design of control unit 4 according to the present invention makes it easily possible to immediately identify a case of patent infringement since one need merely saw open the component in order to expose the channels which are filled with fluid.

What is claimed is:

1. A control unit (4) comprising at least one base (1) and a circuit carrier (2) assigned thereto, and a cover (3) that closes the control unit (4), in which the control unit (4) may be brought to a desired temperature with the aid of a heat-dissipating substrate and/or heat-dissipating components,
wherein
the substrate is accommodated by cooling paths (12), at least inside the control unit (4).

2. The control unit as recited in claim 1,
wherein
the cooling paths (12) are designed as recesses and/or ducts.

3. The control unit as recited in claim 1,
wherein
the cooling paths (12) are designed as flat recesses.

4. The control unit as recited in claim 1,
wherein
the cooling paths (12) are interconnected, and the cooling fluid may circulate within the cooling paths (12).

5. The control unit as recited in claim 1,
wherein
the wide cooling paths (12) are approximately twice as wide as the narrow cooling paths (11).

6. The control unit as recited in claim 1,
wherein
the depth of the wide ducts or cooling paths is approximately half to twice as great as the narrow ducts or cooling paths.

7. The control unit as recited in claim 1,
wherein
the cooling paths (12) are provided in the base (1) and/or in the circuit carrier (2) and/or in the cover (3).

8. The control unit as recited in claim 1,
wherein
the cooling paths (12) have a depth of less than 200 μm, or less than 120 μm, or between 10 μm and 120 μm, or between 50 μm and 120 μm, in particular between 50 μm and 110 μm.

9. The control unit as recited in claim 1,
wherein
the narrow cooling paths (11) have a size between 5 μm and 200 μm, or between 10 μm and 150 μm, or between 80 μm and 120 μm.

10. The control unit as recited in claim 1,
wherein
the wide cooling paths (12) have a size between 100 μm and 10 mm, or between 200 μm and 500 μm, or between 200 μm and 300 μm.

11. The control unit as recited in claim 1,
wherein
the cooling paths (12) are formed in groups (10) and/or in various independent groups (10) in the surface of the base (1), the circuit carrier (2), and/or the cover (3), the individual groups having a flow interconnection, and wherein the cover (3) and/or the base (1) are composed of electrically conductive or electrically insulating material.

12. The control unit as recited in claim 1,
wherein
after the cooling fluid enters the cooling paths (12) of the control unit (4), a certain quantity of the cooling fluid is pumped back out in order to create an underpressure in the closed control unit (4).
